(19) United States
(12) Patent Application Publication
(10) Pub. No.: US 2023/0223200 A1
(43) Pub. Date: Jul. 13, 2023

(54) PCB WITH INTERNAL CAPACITORS AND A MULTILAYER CAPACITANCE PLANE

(71) Applicant: Imagine TF, LLC, Campbell, CA (US)

(72) Inventor: Brian Edward Richardson, Los Gatos, CA (US)

(21) Appl. No.: 17/572,723

(22) Filed: Jan. 11, 2022

(51) Int. Cl. H01G 4/33; H01G 4/232; H01G 4/012; H05K 1/16; H05K 1/02

(52) U.S. Cl. CPC H01G 4/33; H01G 4/232; H01G 4/012; H05K 1/162; H05K 1/0298; H05K 2201/0195; H05K 2201/09672; H05K 2201/0379; H05K 2201/0317; H05K 2201/0187

(57) ABSTRACT

A capacitor device to store electrical charge is disclosed that includes a first unit of a first conductor layer fabricated from a first material. The first conductor layer is sandwiched between two dielectric layers. This assembly is layered on a second unit of a second conductor layer fabricated from a second material and sandwiched between two additional dielectric layers. The first conductor layers are all electrically connected to one another, and the second conductor layers being electrically connected to one another but are not electrically connected to the first conductor. Any multiple of first and second units may be utilized.

### CROSS REFERENCE TO RELATED APPLICATIONS

N/A

### FIELD OF THE PRESENT DISCLOSURE

The present disclosure addresses fabrication of a capacitor film stack within a printed circuit board (PCB), which enables multiple discrete capacitors to be formed within the capacitor film stack. Fabrication of the capacitor film stack includes using two different types of materials for the anodes and cathodes of the capacitor film stack. The use of different types of materials allows for selective etching and the eventual connection of an anode without the connection of a corresponding cathode at a given location and conversely, connection of a cathode without the connection of a corresponding anodes at a different location.

### SUMMARY

The present disclosure describes deploying capacitor film stacks within the layers of a printed circuit board (PCB). Both a stack formed from large continuous films and stacks formed from segmented films are disclosed. Both of these configurations reduce the need for discrete capacitor devices and improve the performance of the PCB assembly.

Various embodiments of the present disclosure teach a capacitor constructed with electrode conductors formed with at least two different materials. By deploying two materials, one for the anodes and another for the cathodes, the conductors can be selectively etched for ease of fabrication and selective connection.

### BRIEF DESCRIPTION OF THE DRAWINGS

The accompanying drawings, where like reference numerals refer to identical or functionally similar elements throughout the separate views, together with the detailed description below, are incorporated in and form part of the specification, and serve to further illustrate embodiments of concepts that include the claimed disclosure, and explain various principles and advantages of those embodiments.

The methods and systems disclosed herein have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

FIG. 1 is a perspective view of a printed circuit board populated with various electrical components.

FIG. 2 is a sectional view of the printed circuit board shown in FIG. 1.

FIG. 3 is a closeup view of a small section of the PCB shown in FIGS. 1-2 showing a supply voltage via connection.

FIG. 4 is a magnified view of part of the section shown in FIG. 3.

FIG. 5 is a still greater magnification of part of the section shown in FIG. 3.

FIG. 6 is an even greater magnification of part of the section shown in FIG. 3.

FIG. 7 is a sectional view of a second small area of the PCB shown in FIG. 2 showing a feed through via.

FIG. 8 is a highly magnified view of the area shown in FIG. 7.

FIG. 9 is a sectional view of a third small area of the PCB shown in FIG. 2 showing a ground via.

FIG. 10 is a highly magnified view an area of the PCB illustrated in FIG. 9.

FIG. 11A is a perspective view of the capacitor stack, and FIG. 11B is an exploded view of the stack.

FIG. 12A is a top plan view of the capacitor stack, and FIG. 12B is a magnified view.

FIGS. 13A and B are perspective views of an alternate embodiment of the capacitor stack.

FIG. 14A is a side section view of the layered stack shown in FIG. 13B, and FIG. 14B is a closeup view of FIG. 14A showing the details of the insulating rig.

FIG. 15A is a closeup view of the layered stack shown in FIG. 14A showing the details of a ground via, and FIG. 15B is a closeup view. showing the details of a voltage via.

FIG. 16A is a top view of a second alternate embodiment of the invention.

FIG. 16B is a top view of a third alternate embodiment of the invention.

FIGS. 17A and 17B are sectional views of a fourth embodiment of the capacitor stack.

FIGS. 18A and 18B show a fifth alternate embodiment of the capacitor stack.

FIG. 19 illustrates a sixth alternate embodiment of the capacitor stack.

FIG. 20 is an electrical diagram of a capacitor with capacitance calculations.

FIGS. 21-23 show reference materials known in the prior art.

### DETAILED DESCRIPTION

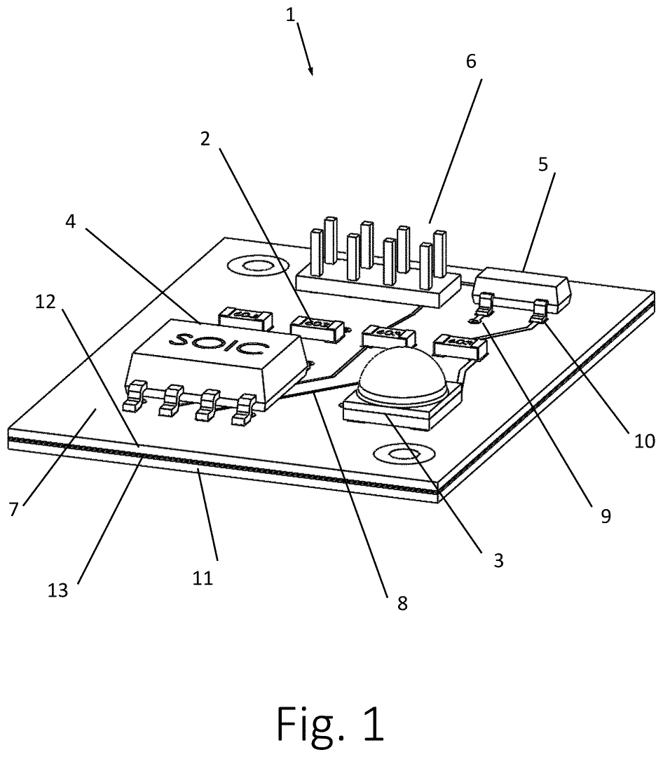

FIG. 1 is a perspective view of a PCB assembly 1 with electrical components assembled onto it. A number of different types of components are shown; chip resistors 2, an LED 3, an integrated circuit (IC) 4, a transistor 5, and a connector 6 are assembled on a printed circuit board (PCB) 7. These and other components are well known to the electronics industry. The components are typically affixed to the PCB 7 with a metal-based solder. Alternatively, the various circuit devices can be assembled on the PCB 7 with conductive ink. One knowledgeable in electronic circuitry could build devices in an unlimited number of configurations to accomplish the requirements of a given PCB assembly 1.

The PCB 7 utilizes circuit traces 8 to make electrical connections from one component to another. The circuit traces 8 are typically located on the top and bottom sides of the PCB 7. It is common to utilize many layers of substrates and many layers of circuit traces 8 to connect the circuit devices. To facilitate the connections between the multiple layers, PCB's often utilize vias 9. The vias 9 are used to electrically connect traces 8 from one PCB layer to another. Conductive pads 10 are used to facilitate the mechanical and electrical connections of the electronic devices to the circuit traces 9. Some complex boards may have over ten layers of substrates and traces. Some of the layers may include a “ground plane” or a “power plane” (not shown). The power or ground planes provide efficient distribution of either power or ground connections to the various components. The planes may be connected by the vias or component leads as prescribed by the circuit design and the configuration of the circuit devices in a given PCB. The planes offer a low impedance connection between devices. Most often the ground plane is spaced from the power plane with “core” or “prepreg” substrate materials. The substrates are typically fabricated from a fiberglass epoxy material, and range in thickness from 50 um to over 100 um. The substrate material used between ground or power planes do have dielectric properties and are not conductive. The sandwich of the power plane and the ground plane with the dielectric core of the substrate creates a small amount of capacitance.

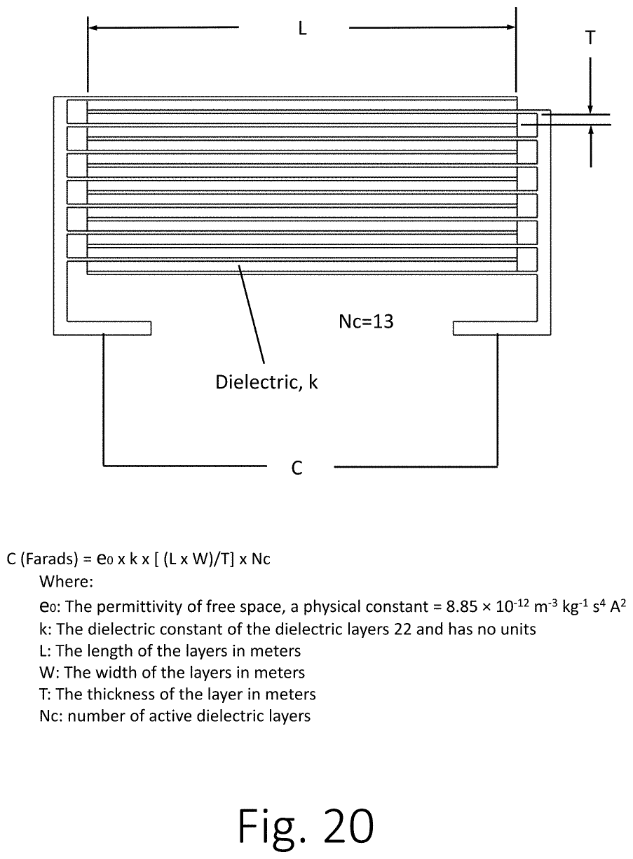

Capacitance in a device allows for the storage of electrical charge. The ability to store charge is measured in Farads. A small PCB assembly with high-speed ICs or power regulation ICs would more than likely require discrete capacitors that would be assembled to the PCB. The discrete capacitors might need to provide hundreds or thousands of micro-Farads of capacitance in multiple locations throughout the PCB assembly. Small capacitors may only have a fraction of a micro-Farad in capacitance. Larger capacitors may have a Farad or more. The equation for capacitance is based on the geometry and physical characteristics of a capacitor (as shown in FIG. 20). The calculation is:

C (Farads)=e₀×k×[(L×W)/T]×Nc

### Where:

e₀: The permittivity of free space, a physical constant=8.85×10⁻¹² m⁻³ kg⁻¹ s⁴ A²

k: The dielectric constant of the dielectric layers 22, unitless

L: The length of the layers in meters

W: The width of the layers in meters

T: The thickness of the dielectric layer in meters

Nc: number of active dielectric layers

It should be noted that for efficient PCB construction, it is generally desirable to have capacitors with a large amount of capacitance (Farads) within as small a package as is possible.

The permittivity of free space is a physical constant and is the same for all capacitors. The dielectric constant, k, is a property of the dielectric material used in the dielectric layers. Dielectric constants k for dielectric materials range from around 4 for silicon dioxide (SiO₂) to greater than 2000 for strontium titanium oxide. One skilled in the art of dielectric materials would be readily able to engineer the selection of the dielectric for a particular application of a capacitor. It is generally preferable for the geometry of the capacitor to be minimized. Length, width, and thickness should be as small as possible. Larger and thicker capacitors not only require more real estate within a PCB but utilize more material, which increases cost. The number of layers, Nc, also affects the cost and to a lesser degree size of the component.

An example calculation of the capacitance created by the dielectric between a current art ground plane and power plane is; for k=10, L=0.1 m, W=0.1 m, t=0.0001 m (100 micrometers) and n=1, the capacitance is 8.85e-9 Farads (8.85 nanoFarads). If the thickness is reduced to t=0.00000001 m (10 nanometers) and the number of layers increased to n=50 the capacitance would be 4.42e-3 (4,420 microFarads or 4,420,000 nanoFarads), an increase of 500,000×. This increase in capacitance can be realized by deploying the disclosed invention within a PCB.

As mentioned above, discrete capacitors are a type of component that is commonly incorporated on a PCB. The PCB assembly disclosed herein does not show any discrete capacitors, as the function of discrete capacitor components is integrated within the layers of the PCB 7.

Referring again to FIG. 1 where the PCB 7 constitutes a top substrate 12 and a bottom substrate 11, with a capacitor stack 13 located between the top 12 and bottom 11 substrates. The order and number of capacitor stacks and substrates in a PCB can vary widely. One skilled in the art of electronic and PCB design could engineer a PCB with many more layers of substrates, traces, capacitor stacks, and with the addition ground and voltage planes.

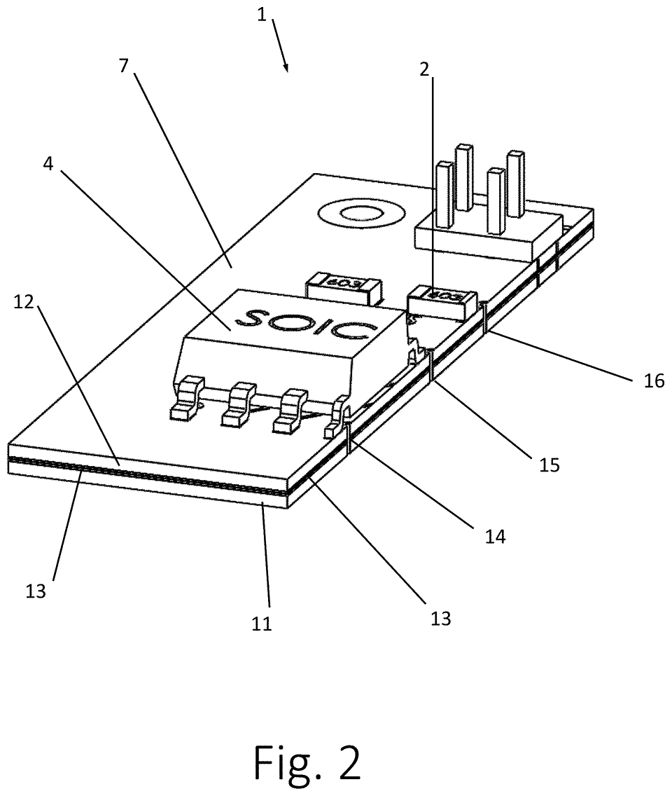

FIG. 2 is a perspective section view that illustrates the connection of the capacitor stack 13 to various vias 14, 15, 16 in the PCB 7. A copper voltage via 14 is shown in proximity to one of the legs of the IC 4.

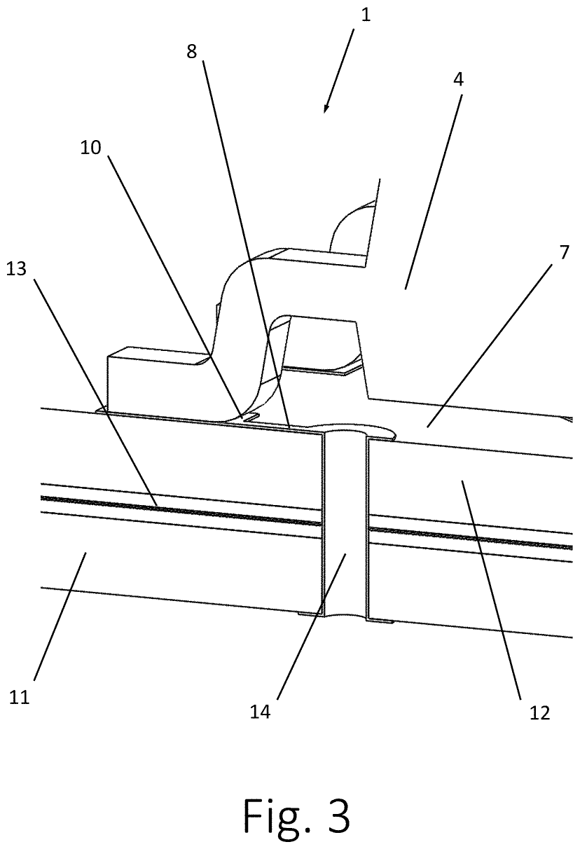

Referring now to FIG. 3, which is a magnified view of the area surrounding the copper voltage via 14. As mentioned above, vias connect traces or pads from one layer of the PCB to another. The copper voltage via 14 is shown as extending through the entire thickness of the PCB 7. This is not always the case. In some instances, the via may only connect and extend to and from a subset of the PCB 7 layers. The copper voltage via 14 is connected to the pad 10 by the circuit trace 8. The via 14 extends through the top substrate 12, the capacitor stack 13, and the bottom substrate 11. The via 14 may or may not be terminated at circuit traces at any of the top or bottom surfaces of these elements. All of the substrate materials are generally not electrical conductors. The trace, pad, and via materials allow electrical conduction. The vias are shown as tubular sleeves. This is common practice within the art.

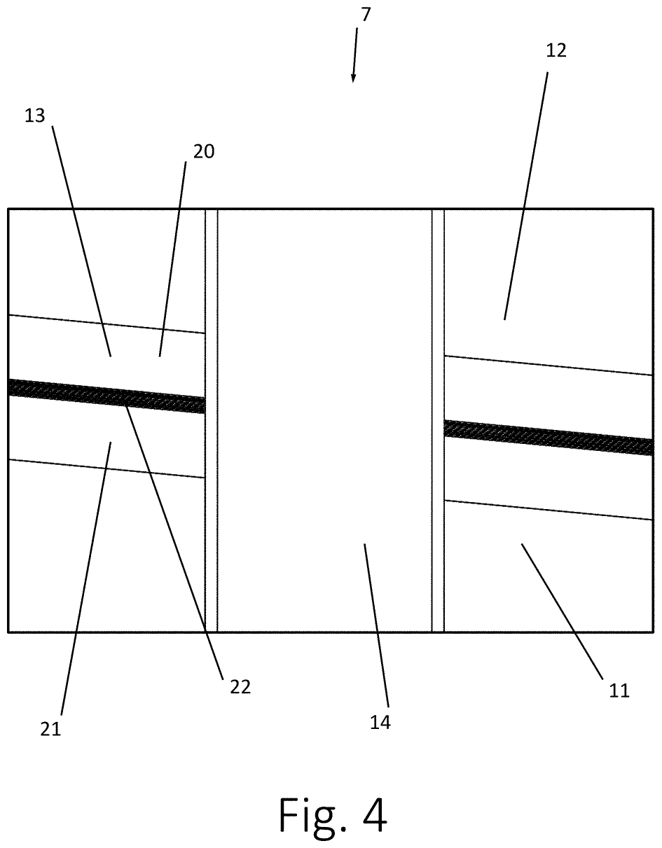

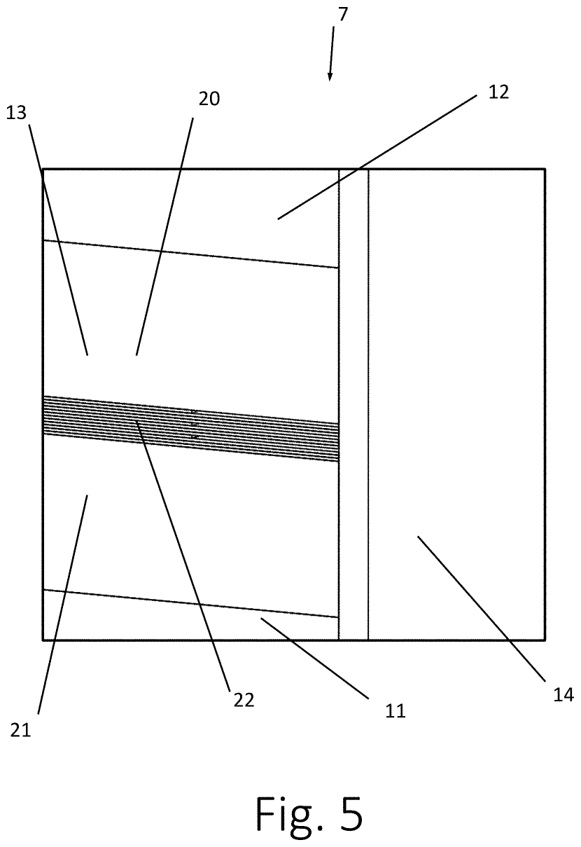

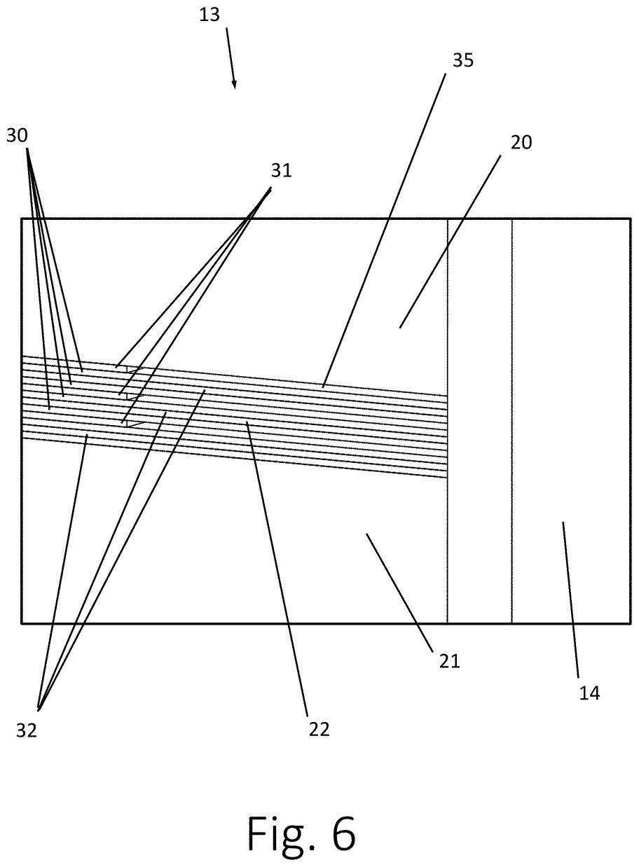

FIG. 4 is a detail view of the immediate area around the copper voltage via 14 and the capacitor stack 13. FIG. 5 and FIG. 6 show that area at even higher magnifications. FIG. 6 shows the various elements of the capacitor stack 13 and their connections or lack of connection to the copper voltage via 14. The capacitor stack 13 includes a top film 20, a capacitor film stack 22, and a bottom film 21. Both the top 20 and bottom 21 films are not electrically conductive. The non-conductive top film 20 and bottom film 21 allow for easier handling during fabrication and etching

The capacitor film stack 22 is formed from a plurality of sandwiched layers including in order a ground metal film 31, a dielectric film 30, a voltage metal film 32, and another dielectric film 30. This pattern of layers can be repeated many times. FIGS. 4-6 show the pattern repeated twice. For many applications, the pattern would be repeated tens or hundreds of times. Both the dielectric films 30 and the voltage metal films 32 make mechanical contact with the copper voltage via 14. The dielectric films 30 are not generally conductive in relationship to the high conductivity of the voltage metal films 32. Therefore, the dielectric films 30 do not conduct electricity to or from the voltage metal via 14. The mechanical contact of the dielectric films 30 is not required for the function of the invention. The voltage metal films 32 do make an electrical connection and conduct electricity to and from the voltage metal via 14. The ground metal films 31 do not make electrical contact with the copper voltage via 14. An insulating donut 35 located between the edge of the ground metal film 31 and the outside diameter of the copper voltage via 14 provides the insulation. The insulating donut 35 is shown as transparent and could be air, another gas, a vacuum, or an insulating solid material. In summary the ground metal films 32 are not electrically connected to the voltage metal via 14, while the voltage metal films 31 are electrically connected.

Preferred thicknesses of the dielectric films range from a few nanometers to approximately a micron. From the equation above and the examples disclosed above, it is apparent that a thinner dielectric layer provides greater capacitance. There are two limiting factors in reducing thickness; manufacturability and operating voltage. Current PCB substrate layers are typically not less than 50 micrometers in thickness. Some advanced materials allow substrates to be made that are slightly thinner than 1 micron. With current semiconductor manufacturing processing, dielectric films that are one atomic layer thick can be produced. These films are <1 nanometer thick. Using these significantly thinner films as the capacitor film 30 greatly increases the resultant capacity. There is a minimum thickness required to ensure that the dielectric film 30 does not break down due to the applied voltage across it. Generally, for SiO₂ one nanometer of thickness is required for every volt applied across the dielectric. The applied voltage is the potential difference between the voltage metal film 32 and the ground metal film 31. The operating voltage of many of today's high-speed electronic devices and circuits range from slightly less than one volt to up to 6 volts. With the use of known semiconductor processes and related types of processes, devices utilizing the technology disclosed herein can be fabricated with dielectric films much thinner than those of the current art. The use of thousands or even hundreds of thousands of nanometers of dielectric material used in current art can be replaced with only a few nanometers of films constructed with the technology disclosed herein. The metal film layers, ground and voltage, are driven by manufacturability and electrical performance requirements. With the current art, the thicknesses of those layers range from a few microns to tens of microns in thickness. With the technology discussed herein, the thickness of the metal films can be greatly reduced, to tens of nanometers in thickness. The thickness limitations would be established by the electrical requirements of the subject circuit.

The materials used for the voltage metal films 32 and for the ground metal films 31 are distinctly different. This allows for selective etching of the layers, to provide necessary electrical connection points. In some embodiments, the ground metal films 31 are etched back with an etchant that only attacks the ground metal films 31, and is non-reactive toward the voltage metal films 32 and the dielectric films 30.

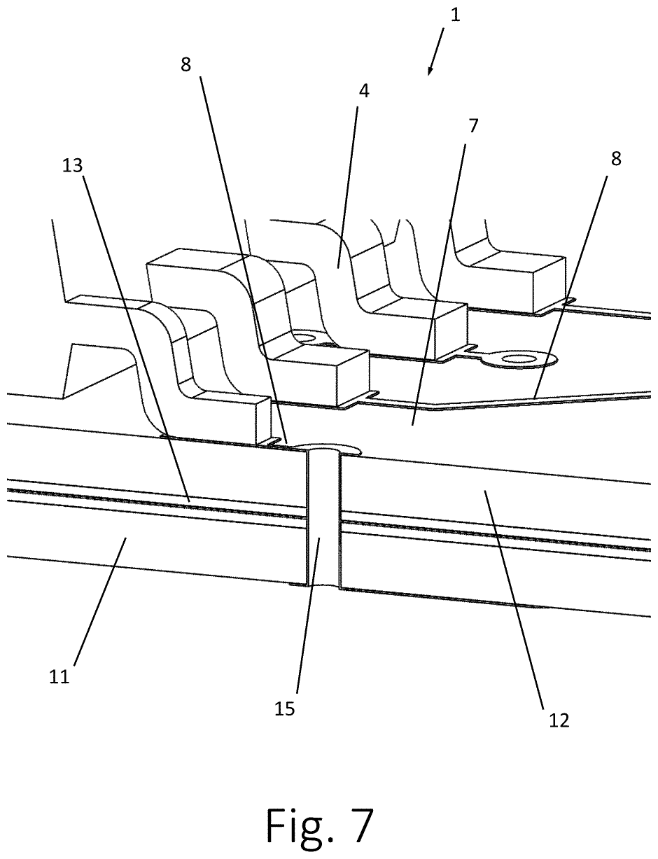

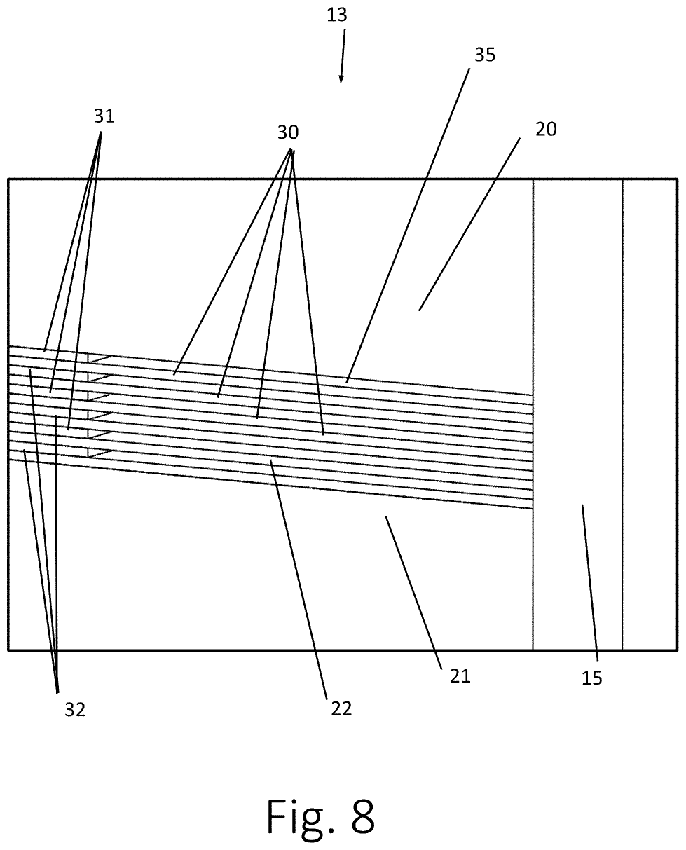

FIGS. 7 and 8 illustrate a copper feed through via 15. A feed through via is one that connects circuit traces 8 on the top of the PCB to the bottom of the PCB without connecting intermediate layers. The details of this bypassed connection can best be seen in FIG. 8. As with the copper voltage via 14, the dielectric films 30 mate to the copper feed through via 15. Neither the voltage metal films 32 nor the ground metal films 31 connect to each other, and more importantly they do not make electrical connections to the copper feed through via 15. During etching, both the voltage metal films 32 and the ground metal films 31 would be etched in order to create the insulation donut 35.

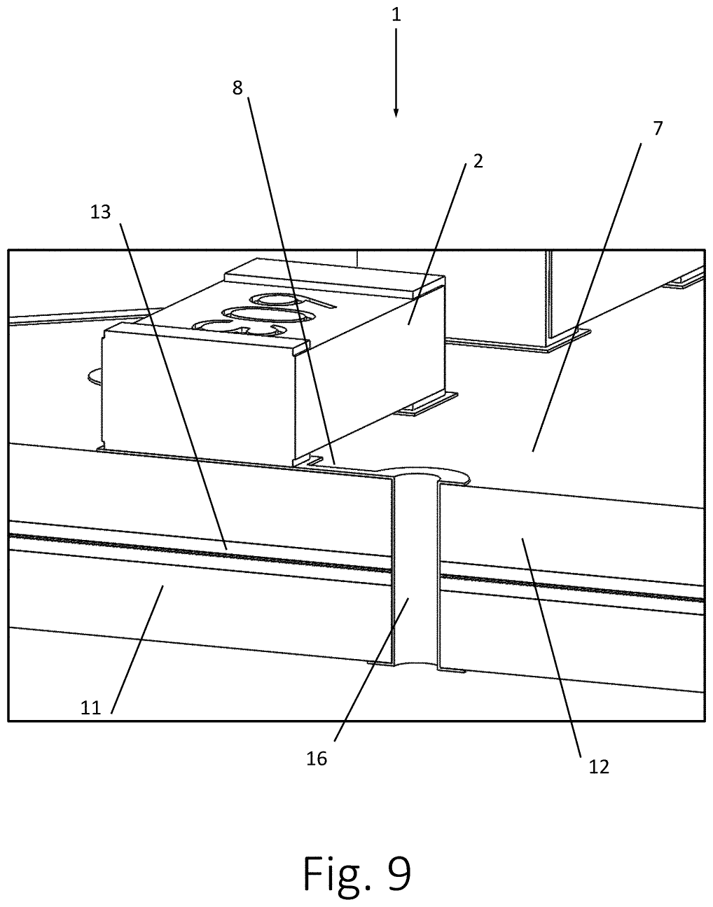

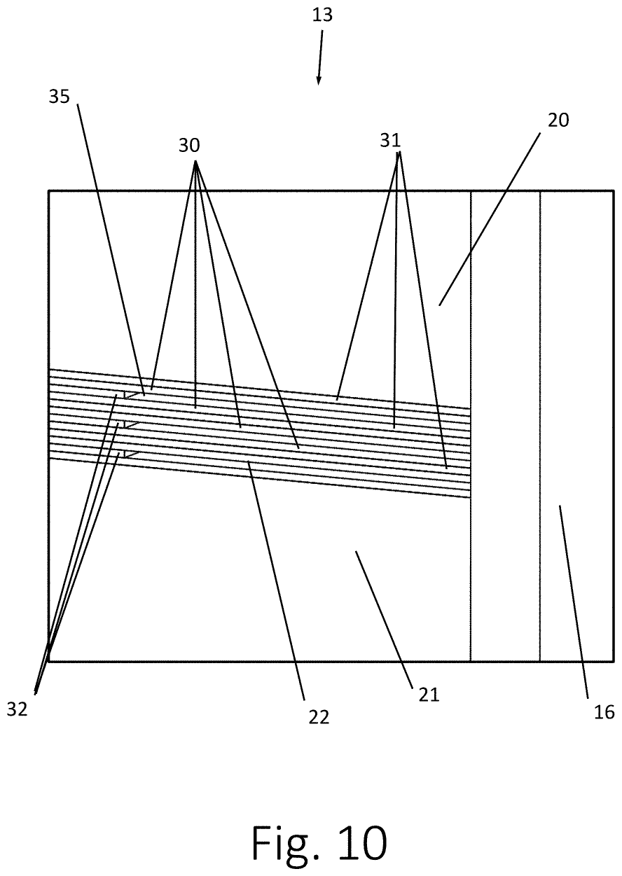

FIGS. 9 and 10 illustrate a copper ground via 16. The copper ground via 16 is connected via to the circuit traces 8 to a common electrical connection with other components on the board. These types of common electrical connections are often called “ground”. The details of the ground connection can best be seen in FIG. 10. As is the case with the copper voltage vias 14 and the copper feed through vias 15, the dielectric films 30 mate to the copper ground via 16. The voltage metal films 32 do not make electrical connection, while the ground metal films 31 do make an electrical connection.

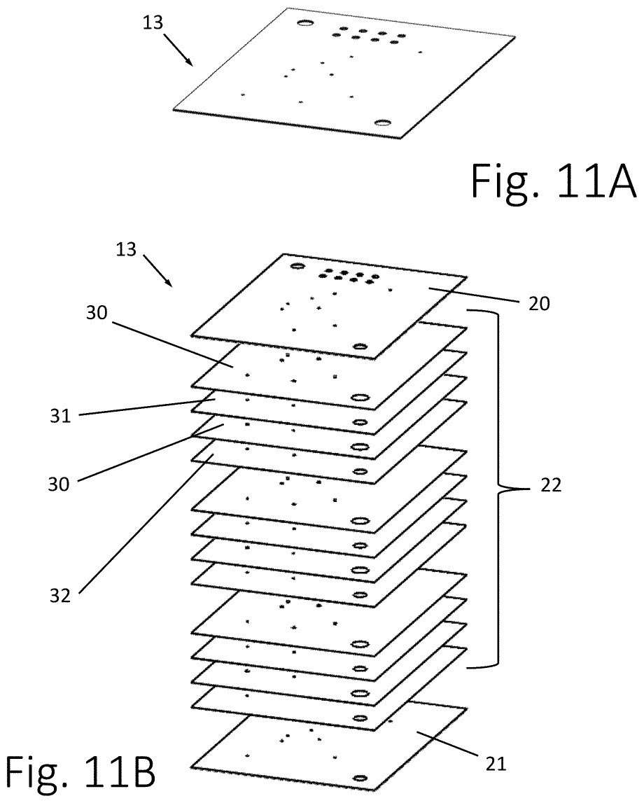

FIGS. 11A and B show the capacitor stack 13 as an assembled sheet (FIG. 11A), and then in an exploded view (FIG. 11B). All of the films—the top film 20, dielectric films 30, the ground metal films 31, the voltage metal films 32, and the bottom films 21—are continuous films of generally the same outline and number and general location of through holes. The various through holes may vary in diameter from layer to layer. Traces, ground planes, and/or power planes can be deployed on the top or bottom of either or both of the top film 20 and the bottom film 21, depending on the functional requirements of the PCB assembly 1.

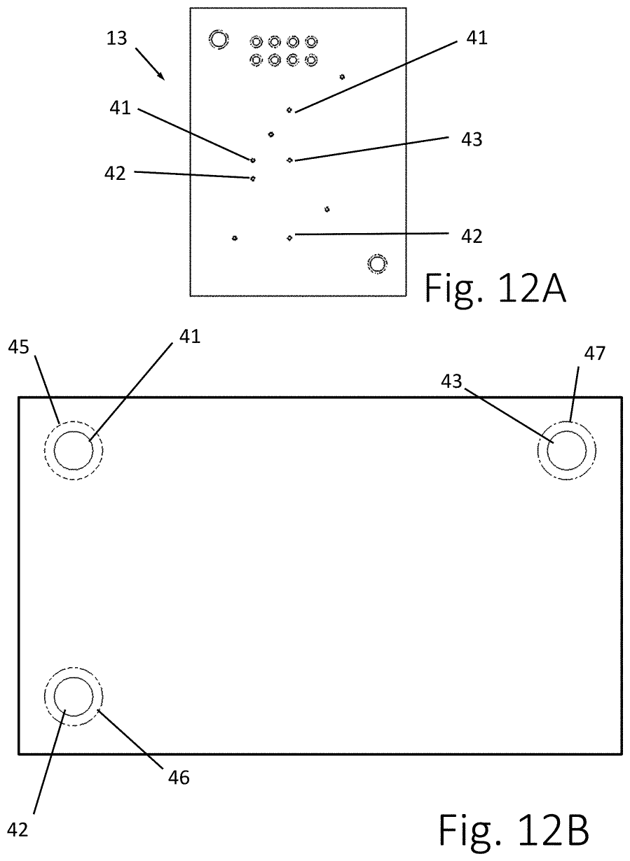

FIG. 12A is a top view of the capacitor stack 13. FIG. 12B is a magnified view of a section of the top of the capacitor stack 13 showing the three types of via configurations, without the copper vias being shown. Referring to the top left corner of FIG. 12B, a ground hole 41 cuts through the top film 20, the dielectric films 30, the ground metal films 31, and the bottom film 21. The diameter of the ground hole 41 is generally the same as the outside diameter of a via associated with the ground hole 41. The hole in the voltage metal film 31, the voltage metal hole 42 is typically larger than the ground hole 41. This larger diameter is shown as a dashed line in that it is not visible thought the opaque films above. The space between the two diameters would be filled by the insulating donut 35. In various embodiments, the larger diameter holes could be created before the films are assembled as a stack. In stack of only a few layers, this would not be a difficult task. When there are many layers of films in the stack, the formation of the different sized holes can be a daunting task. By using different metals for the voltage and ground metal films, the diameter of the voltage metal hole 42 can be increased by using an etchant that only attacks the voltage metal film 32 and not the ground metal film 31.

The lower left corner of FIG. 12B shows the voltage metal hole 42 cutting through the top film 20, the dielectric films 30, the voltage metal films 32, and the bottom film 21. The diameter of the hole through these films is generally the same. The holes in the ground metal films 31 are larger than the voltage hole 42. This larger diameter 46 is shown as a triple dashed line in that it is not visible due to the opaque films above. By using different metals for the ground and voltage films 32, the diameter of the ground metal hole can be as compared to the ground hole 41 diameter by an etchant that only attacks the voltage metal film 32 and not the ground metal film 31. This allows for the fabrication of all of the holes in the capacitor stack 13 with a drill, punch, or laser rather than processing each layer one at a time.

Referring now to the upper right corner of FIG. 12B, the feed through hole 43 is the same diameter as the holes in the top film 20, the dielectric films 30, and the bottom films 21. The both metal holes 47 have larger diameters to electrically isolate them from the via. The increased diameter is created by etching back both the ground metal films 31 and the voltage metal films 32.

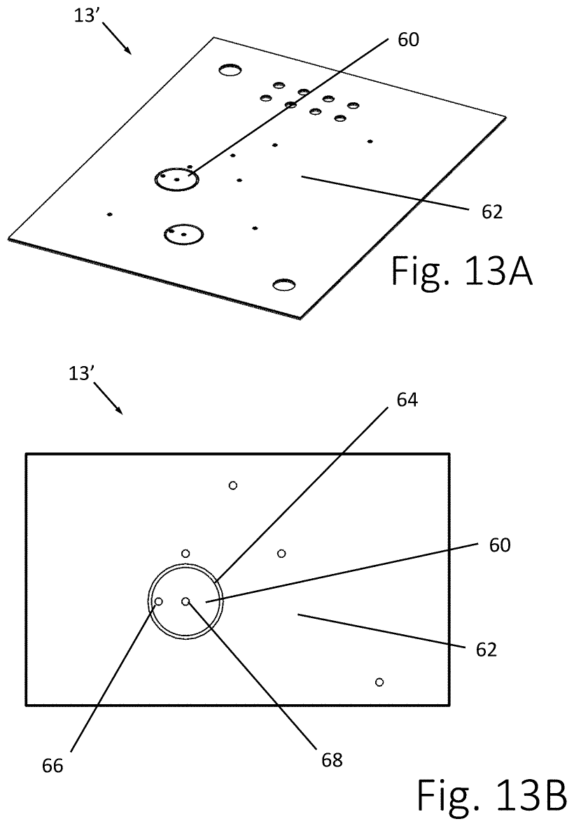

FIGS. 13A and 13B illustrate alternate embodiments of the invention with a capacitor stack 13′ having electrically isolated capacitors 60. FIG. 13B shows the area around one of the electrically isolated capacitors in detail. An isolation ring 64 depicts an area from which all material in all of the films, with the exception of the bottom film 21, is removed. The isolation ring 64 eliminates all electrical connections from a main capacitor area 62 and the electrically isolated capacitor 60.

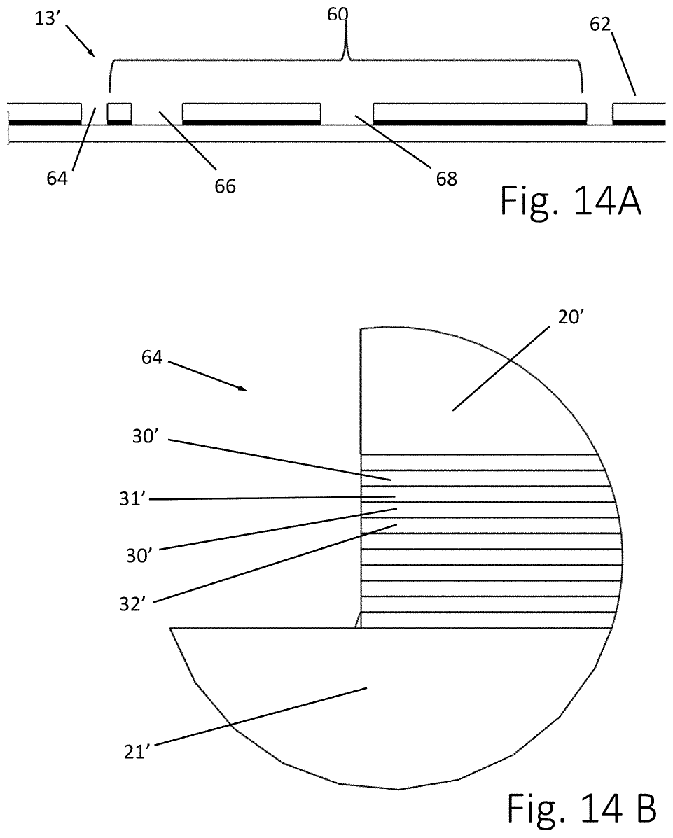

FIG. 14A shows a cross section of a layer of the capacitor stack 13′. Three areas—the isolation ring 64, the ground hole 66, and the voltage hole 68—are shown in further detail in FIGS. 14 B, 15A, and 15B

FIG. 14B illustrates a closeup cross section of the right side of the isolating ring 64 area. The electrically isolated capacitor's ground metal film 31′ and voltage metal films 32′ extend to the isolation ring 64. They do not electrically connect the main capacitor area 62 to the electrically isolated capacitor 60. This lack of connection extends around the entire diameter of the isolation ring 64.

The metal films can be etched back from the isolation ring 64 to provide the desired isolation. The bottom film 21′ does connect the main capacitor area 62 with the electrically isolated capacitor 60. As mentioned above, the bottom film 21′ is not electrically conductive. Depending on manufacturing requirements, the bottom film 21′ may or may not be present.

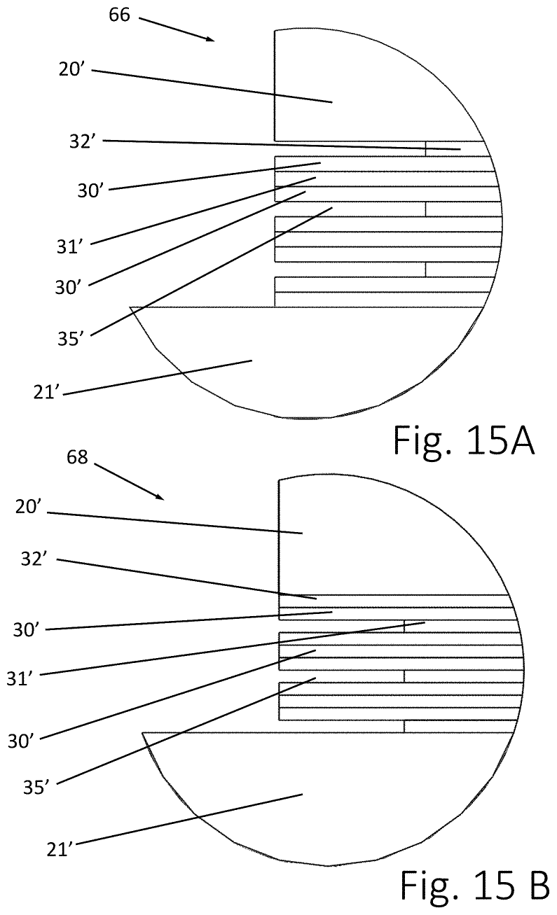

In FIG. 15A, a detailed cross section of the right side of the ground hole 66 is shown. The ground hole 66 shows the inside diameters of the top film 20′, dielectric films 30′, the ground films 31′, and the bottom film 21′ as all being of the same diameter. This facilitates the connection to the inside diameter of a copper ground via 16 when assembled into the PCB. The holes in the voltage metal films 32′ are much larger than the ground hole 66. This larger diameter provide the insulation donut 35′ that electrically insulates the voltage metal film 32′ from a copper ground via.

FIG. 15B is a closeup view of the right side of the voltage hole 68. The voltage hole 68 shows the inside diameters of the top film 20′, dielectric films 30′, the voltage films 32′, and the bottom film 21′ of the same diameter. This facilitates the connection to the inside diameter of the copper voltage via 14 when assembled into the PCB. The ground metal films 31′ are much larger in diameter than the voltage hole 68. The larger diameter provides space for the insulation donut 35′ that electrically insulates the ground metal films 31′ from the copper voltage via 14.

As demonstrated by the calculations above, the amount of capacitance created by the capacitor stack 13 can be significant, in many cases more than is required for the task at hand. Most PCB assemblies employ discrete capacitors. Electronically isolated capacitors 60 can serve the purpose of current art discrete capacitor devices. By adjusting the size of the area of the electronically isolated capacitor 60, the capacitance can be adjusted for a specific purpose. The capacitor stack 13′ is shown with only two electrically isolated capacitors 62. In most assemblies, many more capacitors 62 would be deployed, from hundreds to thousands.

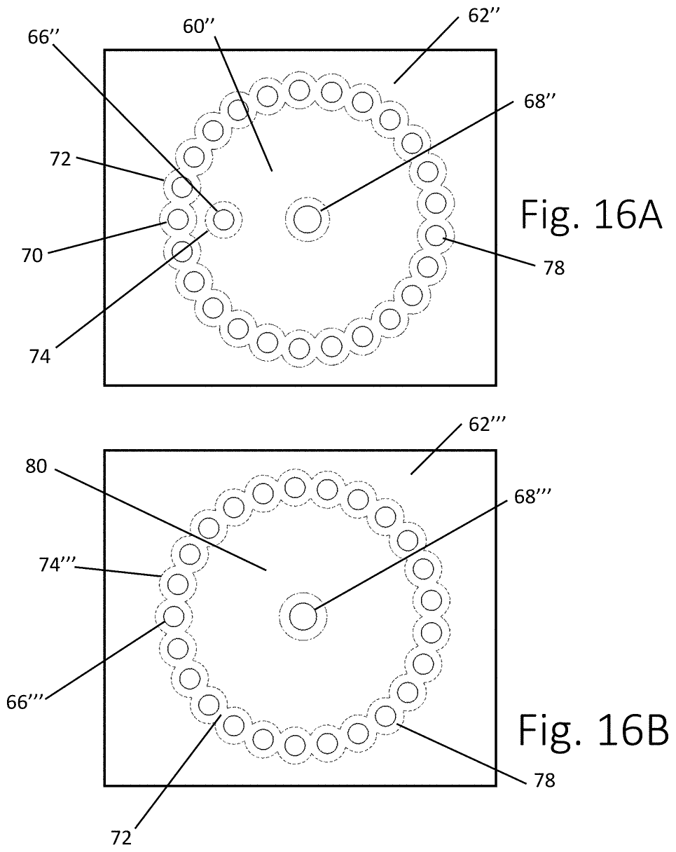

FIG. 16A illustrates further alternate embodiments of the electronically isolated capacitor 60″. A radial array of feed through holes 70 form a radial hole pattern 78 around the voltage hole 68″. The feed through holes 70 are spaced to allow for the material of the top film 20, dielectric films, and bottom film 21 to mechanically constrain the electrically isolated capacitor 60″ within the main capacitor area 62″. Etched back metals 72 are large enough to terminate the electrical connection of both the ground metal films and the voltage metal films of the electronically isolated capacitor 60″ from that of the main capacitor area 62″.

FIG. 16B illustrates still further alternate embodiments of the electrically isolated capacitor 80. As shown, only the voltage metal films 32 are isolated and the ground metal films 31 are not. The holes in the top film 20, the dielectric films 30, the ground metal film 31, and the bottom film 21 are of the same diameter as the ground hole 66′″. This geometry creates a ground metal bridge 72 between adjacent ground metal holes 66′″. The ground metal bridge 72 maintains electrical connection of the ground metal film 31 between the main capacitor area 62′″ and the electrically isolated capacitor 80. The diameter of the voltage metal hole 74′″ is much greater than the ground hole 66′″. This diameter is large enough that the electrical connection of the electrically isolated capacitor 80 is electrically isolated from the main capacitor area 62′″ by virtue of no physical connection.

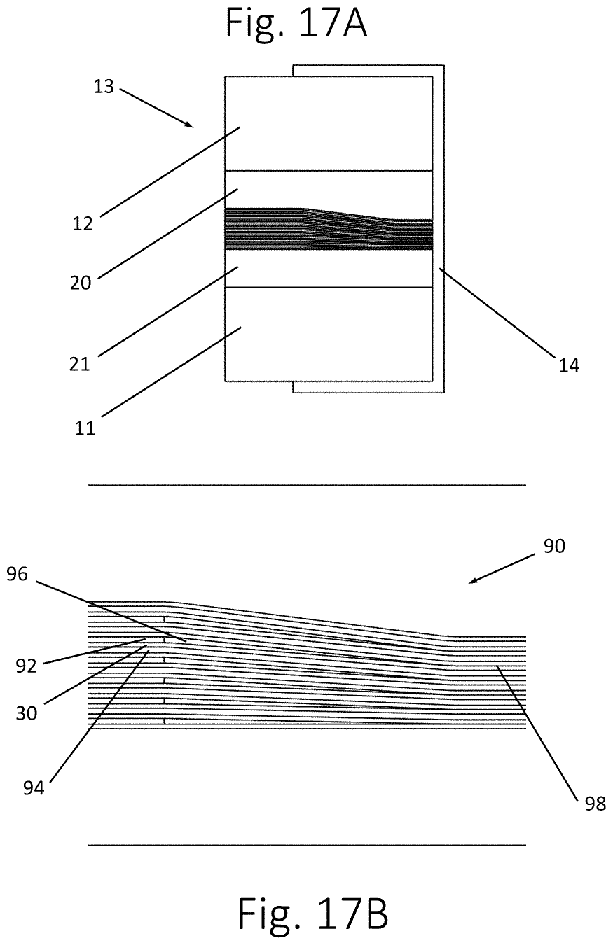

Referring to FIGS. 17A and 17B, still further embodiments that employ a compressed capacitor stack 90 are depicted. In these embodiments the previously disclosed insolating donut 35 is compressed to a point where the dielectric films 30 above and below mate with one another. This compression would more than likely occur in the assembly of the compressed capacitor stack 90 within the PCB when the insulation donut 35 is not a solid material. This compression provides added protection against the etched metal film from making an electrical connection with the associated via.

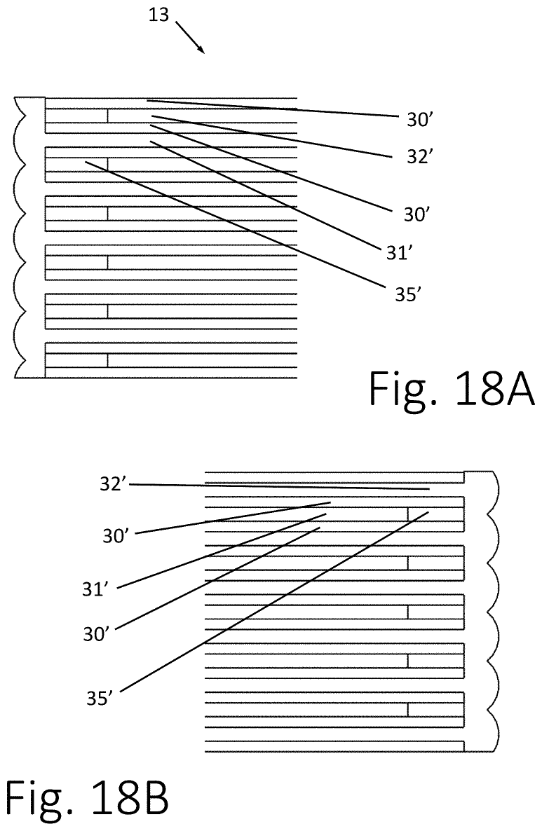

FIGS. 18A and 18B illustrate still other embodiments of the invention. In these embodiments, the voltage and ground films are connected by selectively plating either the voltage film or the ground film. FIG. 18A shows the ground metal films connected with plated metal pads. The plated metal pads are created by electroplating or electroless plating the edges of the holes of the capacitor film stack. The ground film is etched back from the edge in a previous step. In the case of electroplating, the voltage films would be activated with a voltage to selectively build up electroplating until the voltage films are electrically connected. In the case of electroless plating, the metal would not be deposited on the dielectric film. Some metal would be plated to the ends of the ground films. The rate of deposition would be much slower. Proper geometry of the etched background films and thickness of the dielectric ensure there is no electrical connection between the ground and voltage films. The converse, a ground film connection without a voltage film connection, is shown in FIG. 18B.

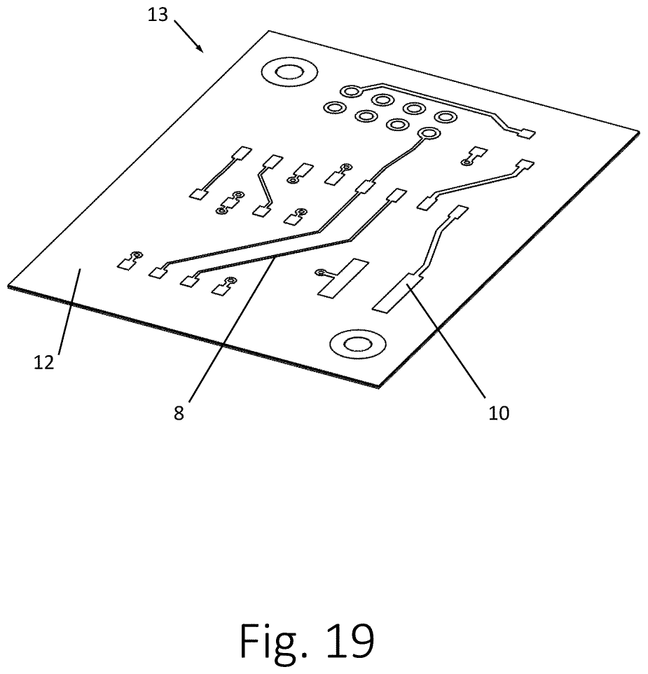

FIG. 19 shows other embodiments of the invention. In this configuration, the capacitor film stack 13 includes circuit traces 8 and pads 10 on the top surface of the top substrate 12.

FIG. 20 sets forth a schematic representation of a multi-film capacitor and the general equation to determine its capacitance.

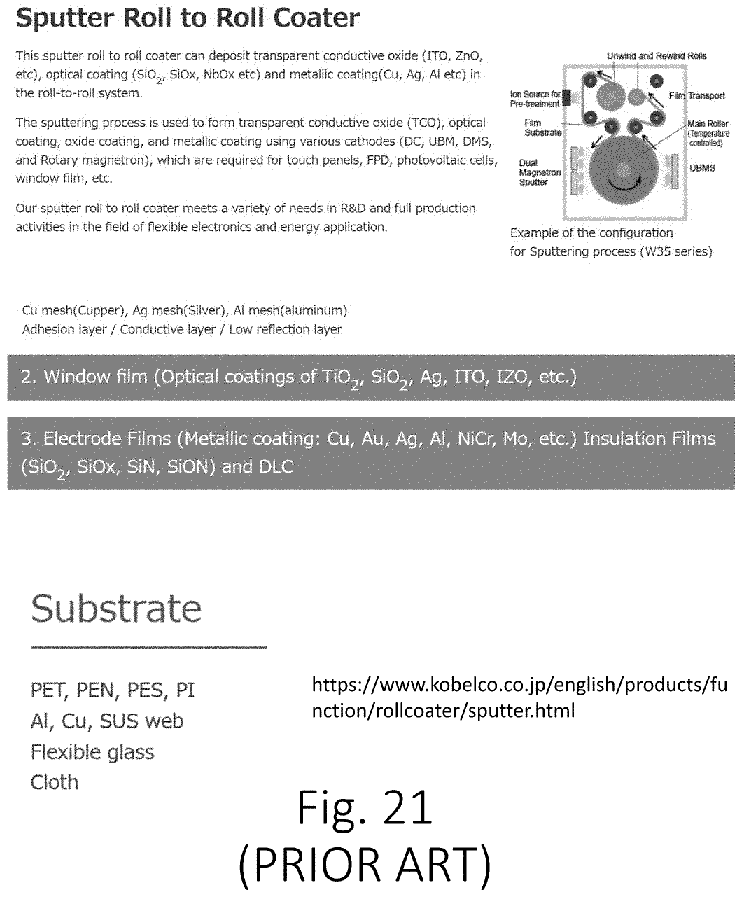

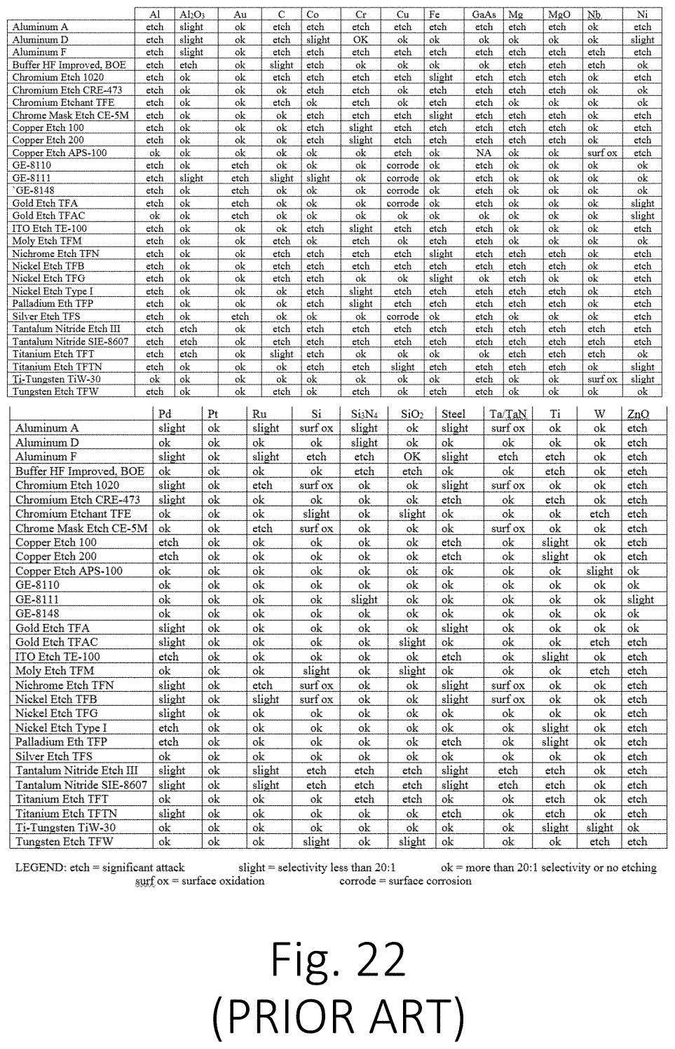

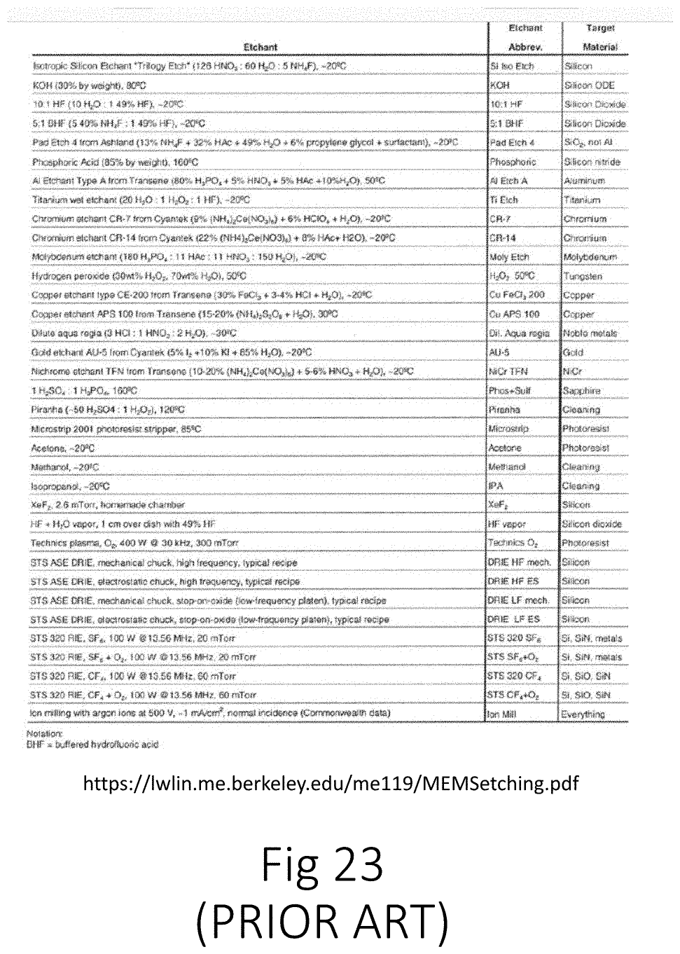

FIGS. 21-23 disclose prior art information on capacitors and materials used as dielectrics and etchants and their effectiveness in etching conductors and dielectrics.

A preferred process to manufacture the preferred embodiment would be to:

1. Deposit a film stack of alternating layers of dielectric, and two different types of metals on top of the bottom substrate. This stack may have tens or hundreds of layers. A top substrate may be added for manufacturability and protection but is not required.

2. Create holes in the stack created in step 1. These holes would correspond to the locations of the vias. These holes would be slightly larger than the metal vias created later in the process.

3. Selectively etch back the voltage films and ground films with different chemistries. A chemistry that etches the ground metal would be applied to the holes that require voltage connection. A different chemistry that etches the voltage metal would be applied to the holes that require ground connection. The feed through holes would be etched with both chemistries.

4. Plate the hole with metal to connect the voltage film and the ground films.

5. Assemble the film within or to other PCB layers. Create holes in the assembly the same size as or slightly smaller than the plated metal in step 3.

6. Finish the fabrication with current PCB fabrication processes.

The description of the present disclosure has been presented for purposes of illustration and description, but is not intended to be exhaustive or limited to the present disclosure in the form disclosed. Many modifications and variations will be apparent to those of ordinary skill in the art without departing from the scope and spirit of the present disclosure. Exemplary embodiments were chosen and described in order to best explain the principles of the present disclosure and its practical application, and to enable others of ordinary skill in the art to understand the present disclosure for various embodiments with various modifications as are suited to the particular use contemplated.

While this technology is susceptible of embodiment in many different forms, there is shown in the drawings and will herein be described in detail several specific embodiments with the understanding that the present disclosure is to be considered as an exemplification of the principles of the technology and is not intended to limit the technology to the embodiments illustrated.

The terminology used herein is for the purpose of describing particular embodiments only and is not intended to be limiting of the technology. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that like or analogous elements and/or components, referred to herein, may be identified throughout the drawings with like reference characters. It will be further understood that several of the Figures are merely schematic representations of the present disclosure. As such, some of the components may have been distorted from their actual scale for pictorial clarity.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” or “according to one embodiment” (or other phrases having similar import) at various places throughout this specification are not necessarily all referring to the same embodiment. Furthermore, the particular features, structures, or characteristics may be combined in any suitable manner in one or more embodiments. Furthermore, depending on the context of discussion herein, a singular term may include its plural forms and a plural term may include its singular form. Similarly, a hyphenated term (e.g., “on-demand”) may be occasionally interchangeably used with its non-hyphenated version (e.g., “on demand”), a capitalized entry (e.g., “Software”) may be interchangeably used with its non-capitalized version (e.g., “software”), a plural term may be indicated with or without an apostrophe (e.g., PE's or PEs), and an italicized term (e.g., “N+1”) may be interchangeably used with its non-italicized version (e.g., “N+1”). Such occasional interchangeable uses shall not be considered inconsistent with each other.

It is noted at the outset that the terms “coupled,” “connected”, “connecting,” “electrically connected,” etc., are used interchangeably herein to generally refer to the condition of being electrically/electronically connected. Similarly, a first entity is considered to be in “communication” with a second entity (or entities) when the first entity electrically sends and/or receives (whether through wireline or wireless means) information signals (whether containing data information or non-data/control information) to the second entity regardless of the type (analog or digital) of those signals. It is further noted that various Figures (including component diagrams) shown and discussed herein are for illustrative purpose only, and are not drawn to scale.

While specific embodiments of, and examples for, the system are described above for illustrative purposes, various equivalent modifications are possible within the scope of the system, as those skilled in the relevant art will recognize. For example, while processes or steps are presented in a given order, alternative embodiments may perform routines having steps in a different order, and some processes or steps may be deleted, moved, added, subdivided, combined, and/or modified to provide alternative or sub-combinations. Each of these processes or steps may be implemented in a variety of different ways. Also, while processes or steps are at times shown as being performed in series, these processes or steps may instead be performed in parallel, or may be performed at different times.

What is claimed is:

1. A capacitor device comprising:
at least one first conductor layer fabricated from a first material;
at least one second conductor layer fabricated from a second material; and
a plurality of dielectric layers; wherein
each of the first conductor layers are sandwiched between a pair of dielectric layers;
each of the second conductor layers are sandwiched between a pair of dielectric layers;
each of the first conductor layers are electrically connected to one another;
each of the second conductor layers are electrically connected to one another and are not electrically connected to the first conductor layers, the device being adapted to store electrical charge.

2. The device according to claim 1, wherein at least one of the conductor layers is aluminum or an alloy thereof.

3. The device according to claim 1, wherein at least one of the conductor layers is copper or an alloy thereof.

4. The device according to claim 1, wherein at least one of the conductor layers is nickel or an alloy thereof.

5. The device according to claim 1, wherein at least one of the conductor layers is titanium or an alloy thereof.

6. The device according to claim 1, wherein at least one of the conductor layers is tungsten or an alloy thereof.

7. The device according to claim 1, wherein at least one of the conductor layers is silicon or an alloy thereof.

8. The device according to claim 1, wherein at least one of the conductor layers is chromium or an alloy thereof.

9. The device according to claim 1, wherein at least one of the conductor layers is molybdenum or an alloy thereof.

10. The device according to claim 1, wherein at least one of the conductor layers is gold or an alloy thereof.

11. The device according to claim 1, wherein at least one of the conductor layers is silver or an alloy thereof.

12. The device according to claim 1, wherein at least one of the dielectric layers is formed from a solid material.

13. The device according to claim 1, wherein at least one electrical connection to at least one of the first conductor layers is isolated from an electrical connection of the second conductive layer by a layer of insulating material.

14. The device according to claim 1, wherein at least one electrical connection to at least one of the first conductor layers is isolated from an electrical connection of the second conductive layer by an air gap.

15. The device according to claim 1, wherein the conductor layers and the dielectric layers are stacked directly on top of one another.

16. The device according to claim 1, wherein the resultant capacitor device is located within an integrated circuit.

17. The device according to claim 1, wherein the resultant capacitor device is rolled into a cylindrical geometry.

18. The device according to claim 1, wherein the conductor layers and the dielectric layers are mounted on a substrate.

19. The device according to claim 1, where the conductor layers and the dielectric layers are mounted on a substrate that comprises trenches that are at least twice as wide as the combined thickness of the stacked conductor layer and dielectric layers.

20. A capacitor device comprising:
at least two first conductor layers;
at least two second conductor layers; and
a plurality of dielectric layers; wherein
each of the first conductor layers are sandwiched between a pair of dielectric layers;
each of the second conductor layers are sandwiched between a pair of dielectric layers;
each of the first conductor layers are electrically connected to one another;
each of the second conductor layers are electrically connected to one another and are not electrically connected to the first conductor layers, the device being adapted to store electrical charge.

21. The device according to claim 20, wherein the conductor layers and the dielectric layers are mounted on a substrate.

22. The device according to claim 1, wherein the dielectric layers are less than 100 nm in thickness.

23. The device according to claim 1, wherein there are more than 5 dielectric layers with the same sized features, holes, and cuts.

24. A capacitor film stack comprising:
at least ten first conductor layers fabricated from a first material;
at least ten second conductor layers fabricated from a second material; and
a plurality of dielectric layers; wherein
each of the first conductor layers are sandwiched between a pair of dielectric layers;
each of the second conductor layers are sandwiched between a pair of dielectric layers;
a bottom non-conducting film substrate;
a top non-conducting film.

25. The device according to claim 1, wherein there are discrete isolated areas within the device to create discrete capacitance areas.

26. The device according to claim 25, wherein discrete isolated areas within the device are created by a series of holes.

27. The device according to claim 1, wherein all of the first conducting layers are connected to one another by vias normal in direction to the plane of the layer; and wherein there all of the second conducting layers are connected to one another by vias normal in direction to the plane of the layer.
